(19) United States
(12) Patent Application Publication
(10) Pub. No.: US 2026/0120934 A1
(43) Pub. Date: Apr. 30, 2026

(54) POWER ELECTRONIC TRANSFORMER WITH COOLING UNIT

(71) Applicant: Hitachi Energy Ltd, Zürich (CH)

(72) Inventors: Pascal Lutz, Neuenhof (CH); Stefanie Heinig, Basel (CH); Remo Baumann, Lenzburg (CH); Thomas Schwarzmaier, Wettingen (CH)

(21) Appl. No.: 19/151,818

(22) PCT Filed: Feb. 22, 2023
(86) PCT No.: PCT/EP2023/054476

§ 371 Date: Jul. 29, 2025

(51) Int. Cl. H01F 27/10; H01F 27/02; H01F 27/16; H05K 7/20

(52) U.S. Cl. CPC H01F 27/105; H01F 27/027; H01F 27/16; H05K 7/209; H05K 7/20936

(57) ABSTRACT

A power electronic transformer, including at least one first voltage unit including first voltage power electronics building blocks, at least one second voltage unit including second voltage power electronics building blocks, the first voltage being lower than the second voltage, and a two-phase cooling unit including a two-phase cooling medium for cooling the at least one second voltage unit. The two-phase cooling unit allows for an improved overall system performance of the transformer regarding costs, effort for maintenance, risk of malfunction or failure, and weight and footprint of the construction.

### CROSS REFERENCE TO RELATED APPLICATIONS

This application is a 35 U.S.C. § 371 national stage application of International Application No. PCT/EP2023/054476 filed on Feb. 22, 2023, the disclosures and content of which are incorporated by reference herein in their entirety.

### BACKGROUND

The present disclosure relates to a power electronic transformer with a cooling unit.

It is known to provide a power electronic transformer, e. g. a medium voltage solid state transformer with different cooling circuits using different cooling media for cooling different elements such as, e. g., power electronics building blocks (PEBBs), or transformers. Reasons for providing different cooling circuits are different voltage levels at which corresponding elements operate and a risk of electrolysis current corrosion for medium voltage PEBBs.

Herein “low voltage” is used to describe voltages of up to 1500 V DC, and “medium voltages” is used to describe voltages between 1 kV and 35 kV. Further, the term “medium voltage”, e.g., within the context of a “medium voltage unit” or a “medium voltage PEBB” is intended to indicate a voltage between a heatsink of the respective PEBB and earth potential.

More specifically, medium frequency transformers and low voltage PEBBs are typically cooled by a cooling circuit or unit with tap water as cooling medium because a medium frequency transformer heatsink arrangement is usually on ground potential and low voltage PEBBs are on low voltage potential, and in view of this, it is not necessary, to use de-ionized water as a corresponding cooling medium.

Further, a separate de-ionized water-cooling circuit is provided for cooling the medium voltage PEBBs or other systems which are on medium or higher voltage level, due to the risk of electrolysis current corrosion.

Accordingly, two different cooling circuits are provided for cooling a corresponding power electronic transformer. This contributes to the complexity of the device and results in a high number of parts being required, and also in the device taking up a large overall volume.

FIG. 1 schematically illustrates a prior art power electronic transformer 200. The transformer 200 comprises a first water cooling unit 210 with de-ionized water as cooling medium for cooling medium voltage PEBBs 300. The first water cooling unit 210 typically comprises a de-ionized water to air heat exchanger or a de-ionized water to tap water heat exchanger.

A second water cooling unit 220 is provided for cooling low voltage PEBBs 310 and a medium frequency transformer 320. The second water cooling unit 220 uses ordinary water as cooling medium and may comprise a water to air heat exchanger. These two water cooling units 210, 220 significantly contribute to the transformer 200 being a heavy, complex and bulky construction consisting of a high number of parts with a non-negligible risk of faulty operation.

Therefore, there is a need for a power electronic transformer having improved cooling features.

This object is achieved by the subject-matter of the independent claim. Dependent claims refer to preferred embodiments. Additional and/or alternative aspects of the present disclosure are discussed in the specification and in the aspects.

### SUMMARY

According to the present disclosure a power electronic transformer is provided that comprises at least one first voltage unit operating at a first voltage or voltage range comprising one or more first voltage power electronics building blocks, and at least one second voltage unit for operating at a second voltage or voltage range comprising one or more second voltage power electronics building blocks. The first voltage or voltage range is lower than the second voltage or voltage range. The power electronic transformer further comprises a two-phase cooling unit comprising a two-phase cooling medium for cooling the at least one second voltage unit.

Herein, the term “two-phase cooling unit” is generally understood to describe a cooling unit having a closed conduit and a cooling medium provided within the conduit, the cooling medium generally being partly in its liquid phase and partly in its gaseous phase.

The two-phase cooling unit allows for an improved overall system performance of the transformer regarding costs, effort for maintenance, risk of malfunction or failure, and weight and footprint of the construction. Specifically, a compact design is enabled due to the high power of the two-phase cooling unit. Further, it is not necessary to provide a cooling unit using de-ionized water as a cooling medium. This enables a much simpler overall construction of the transformer as well as more cost-effective operation.

Besides, the cooling medium used in the two-phase cooling unit may be a cooling liquid having dielectric characteristics that enable easy connection to a tap water cooling unit. This allows for a particularly effective, robust and reliably construction.

A further benefit of a two-phase cooling—as compared to a single-phase cooling—is that the cooling power for respective components in series is the same as for respective components in parallel arrangement. That allows for additional degrees of freedom with respect to the design of PEBBs and transformers.

The two-phase-cooling unit may be configured to cool the corresponding components of the transformer in a manner suitable for safe operation of the transformer.

Various embodiments may implement the following features:

The two-phase cooling unit may comprise or consist of a thermosyphon. A thermosyphon is operated by gravity. Therefore, the thermosyphon can be constructed without any moving parts. In this way, a particularly uncomplicated and reliable construction is enabled.

Herein, the term “thermosyphon” is generally understood to describe a device in which a cooling medium is circulated in a closed conduit by convection caused by a difference in density between hot and cold portions of the cooling medium.

Advantageously, the two-phase cooling unit may be configured to electrically isolate the two-phase cooling medium from the at least one second voltage unit. For example, the two-phase cooling unit may comprise a conduit for conducting the two-phase cooling medium, the conduit comprising or consisting of a non-metallic tube. In this case, the conduit may further comprise a metallic fitting for holding the non-metallic tube vis-à-vis a remainder of the transformer.

The power electronic transformer may further comprise a water-cooling unit for cooling the two-phase cooling medium. The water-cooling unit may be configured to use tap water as a coolant fluid. In this way, particularly a low-cost coolant can be used.

The water-cooling unit may comprise a water-to-air heat exchanger. This enables particularly effective heat removal.

The water-cooling unit may be configured to use tap water from site. This is advantageous because no corresponding pump is required to convey the water.

The water-cooling unit may be configured to further cool the at least one first voltage unit. In this way, it is not necessary to provide a separate cooling device for cooling the at least one first voltage unit.

The power electronic transformer may further comprise at least one frequency transformer. In this case, the water-cooling unit may be further configured to cool the at least one frequency transformer. In this way, it is not necessary to provide a separate cooling device for cooling the at least one frequency transformer.

The at least one frequency transformer may be a medium frequency transformer.

The two-phase cooling unit may be a pumped two-phase cooling unit. In this way, the cooling unit is particularly effective.

The power electronic transformer may further comprise a two-phase-to-air heat exchanger configured to cool the two-phase cooling unit.

The power electronic transformer may further comprise a two-phase-to-water heat exchanger configured to cool the two-phase cooling unit. Said water may be ordinary tap water.

The two-phase cooling unit may be configured to further cool the at least one first voltage unit. In this way, it is not necessary to provide a separate cooling device for cooling the at least one first voltage unit.

The power electronic transformer may further comprise at least one frequency transformer. In this case, the water-cooling unit may be further configured to cool the at least one frequency transformer. In this way, it is not necessary to provide a separate cooling device for cooling the at least one frequency transformer.

The at least one frequency transformer may be a medium frequency transformer.

The PEBBs may comprise power semiconductors.

The power electronic transformer may comprise a plurality of first voltage units comprising first voltage power electronics building blocks.

The power electronic transformer may comprise a plurality of second voltage units comprising second voltage power electronics building block.

The power electronic transformer may comprise a plurality of frequency transformers.

The at least one first voltage unit may comprise at least one printed circuit board assembly comprising at least partially the first voltage power electronics building blocks.

The at least one second voltage unit may comprise at least one printed circuit board assembly comprising at least partially the second voltage power electronics building blocks. The first voltage may be equal to or less than 1500 V DC.

The medium frequency may be at least 500 Hz.

In particular, the present disclosure comprises the following aspects:
1. A power electronic transformer, comprising
   at least one first voltage unit for operating at a first voltage comprising one or more first voltage power electronics building blocks,
   at least one second voltage unit for operating at a second voltage comprising one or more second voltage power electronics building blocks,
   the first voltage being lower than the second voltage, and
   a two-phase cooling unit comprising a two-phase cooling medium for cooling the at least one second voltage unit.
2. The power electronic transformer of aspect 1, wherein the two-phase cooling unit comprises a thermosyphon.
3. The power electronic transformer of any of the preceding aspects, wherein the two-phase cooling unit is configured to electrically isolate the two-phase cooling medium from the at least one second voltage unit.
4. The power electronic transformer of any of the preceding aspects, wherein the two-phase cooling unit comprises a conduit for conducting the two-phase cooling medium, the conduit comprising a non-metallic tube.
5. The power electronic transformer of aspect 4, wherein the conduit further comprises a metallic fitting for holding the non-metallic tube.
6. The power electronic transformer of any of the preceding aspects, further comprising a water-cooling unit for cooling the two-phase cooling medium.
7. The power electronic transformer of aspect 6, wherein the water-cooling unit is configured to use tap water as a coolant fluid.
8. The power electronic transformer of aspect 6 or 7, wherein the water-cooling unit comprises a water-to-air heat exchanger.
9. The power electronic transformer of any of aspects 6 to 8, comprising the features of aspect 7, wherein the water-cooling unit is configured to use tap water from site.
10. The power electronic transformer of any of aspects 6 to 9, wherein the water-cooling unit is configured to further cool the at least one first voltage unit.
11. The power electronic transformer of any of aspects 6 to 10, further comprising at least one frequency transformer, the water-cooling unit being further configured to cool the at least one frequency transformer.
12. The power electronic transformer of aspect 11, wherein the at least one frequency transformer is a medium frequency transformer.
13. The power electronic transformer of any of aspects 1 to 5, wherein the two-phase cooling unit is a pumped two-phase cooling unit.
14. The power electronic transformer of aspect 13, further comprising a two-phase-to-air heat exchanger configured to cool the two-phase cooling medium.
15. The power electronic transformer of aspect 13, further comprising a two-phase-to-water heat exchanger configured to cool the two-phase cooling medium.
16. The power electronic transformer of any of aspects 13 to 15, wherein the two-phase cooling unit is configured to further cool the at least one first voltage unit.
17. The power electronic transformer of any aspects 13 to 16, further comprising at least one frequency transformer, the two-phase cooling unit being further configured to cool the at least one frequency transformer.
18. The power electronic transformer of aspect 17, wherein the at least one frequency transformer is a medium frequency transformer.
19. The power electronic transformer of any of the preceding aspects, comprising a plurality of first voltage units comprising one or more first voltage power electronics building blocks, and/or a plurality of second voltage units comprising one or more second voltage power electronics building blocks.
20 The power electronic transformer of any of the preceding aspects, comprising the features of any of aspects 11, 12, 17, and 18, comprising a plurality of frequency transformers.
21. The power electronic transformer of any of the preceding aspects, wherein the at least one first voltage unit comprises at least one printed circuit board assembly comprising the first voltage power electronics building blocks.
22. The power electronic transformer of any of the preceding aspects, wherein the at least one second voltage unit comprises at least one printed circuit board assembly comprising the second voltage power electronics building blocks.
23. The power electronic transformer of any of the preceding aspects, wherein the first voltage is equal to or less than 1500 V DC.
24. The power electronic transformer of any of the preceding aspects, comprising the features of any of aspects 12 and 18, wherein the medium frequency is at least 500 Hz.

### SHORT DESCRIPTION OF THE DRAWINGS

The subject-matter of the disclosure will be explained in more detail with reference to preferred exemplary embodiments which are illustrated in the attached drawings.

FIG. 1 is a schematic illustration of an electronic power converter according to the prior art.

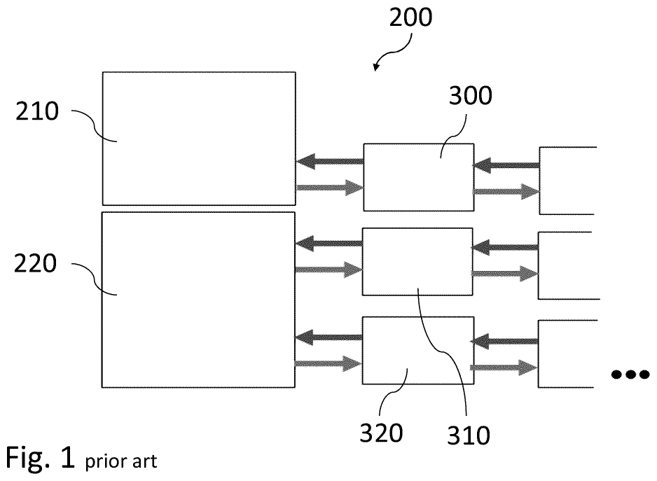

FIG. 2 is a schematic illustration of an electronic power converter according to a first embodiment.

FIG. 3 is a schematic illustration of an electronic power converter according to a further embodiment.

### DETAILED DESCRIPTION

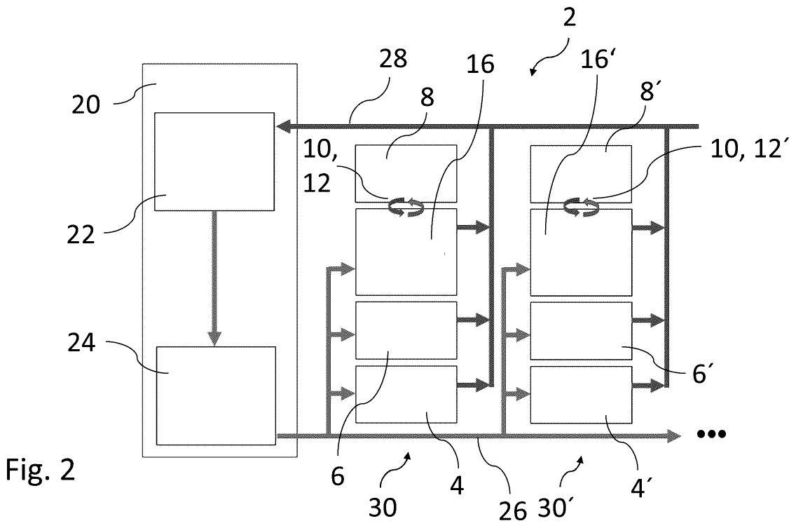

FIG. 2 is a schematic illustration of a power electronic transformer 2 according to a first embodiment. The power electronic transformer 2 comprises a transformer 4, for example in the form of a medium frequency transformer on ground potential, a first voltage unit 6, for example in form of or comprising a plurality of low voltage power electronics building blocks (PEBBs) and a second voltage unit 8, for example in form of or comprising a plurality of medium voltage PEBBs.

The power electronic transformer 2 further comprises a two-phase cooling unit 10 comprising a two-phase cooling medium for cooling the second voltage unit 8.

The two-phase cooling unit 10 may consist of or comprise at least one thermosyphon 12.

The two-phase cooling unit 10 may be advantageously configured to provide an electric isolation between the cooling medium of the two-phase cooling unit 10 and the second voltage unit 8.

The transformer 2 further comprises a two-phase-to-water-cooling unit or heat exchanger 16 for cooling the two-phase cooling medium.

The transformer 2 further comprises a water-cooling unit 20 for cooling the two-phase cooling medium in the two-phase-to-water-cooling unit 16. Advantageously, the water-cooling unit 20 may be configured to use tap water as coolant. Particularly, the water-cooling unit 20 comprises a tap-water pump 24 for pumping the tap water through the water-cooling unit 20.

The transformer 2 further comprises a water-to-air heat exchanger 22 configured to cool the tap water used as coolant in the water-cooling unit 20.

The water-cooling unit 20 is further configured to cool the first voltage unit 6 and the transformer 4. The water-cooling unit 20 may comprise a tubing that runs in form of a parallel connection past the first voltage unit 6, the two-phase to water cooling unit 16, and the transformer 4 for cooling them, as schematically indicated in FIG. 2. Said tubing is indicated by reference number 26 and 28, wherein 26 denotes the colder flow of water for cooling and 28 denotes the warmer flow of water after cooling.

In the illustrated example, the transformer 2 further comprises at least one further transformer 4′, at least one further first voltage unit 6′, and at least on further second voltage unit 8′. The water-cooling unit 20 is further configured to cool these last-mentioned components 4′, 6′, 8′ in analogy to the corresponding first-mentioned components 4, 6, 8. Particularly, the transformer 2 may comprise a plurality of modular cells 30, 30′, each cell comprising or consisting of a respective transformer 4, 4′, a respective first voltage unit 6, 6′, particularly disposed above the respective transformer 4, 4′, and a respective second voltage unit 8, 8′, particularly disposed above the respective first voltage unit 6, 6′. In this case, the two-phase cooling unit 10 advantageously comprises a plurality of thermosyphons 12, 12′ with each cell 30, 30′ comprising one thermosyphon for cooling the respective second voltage unit 8, 8′, as indicated schematically in FIG. 2.

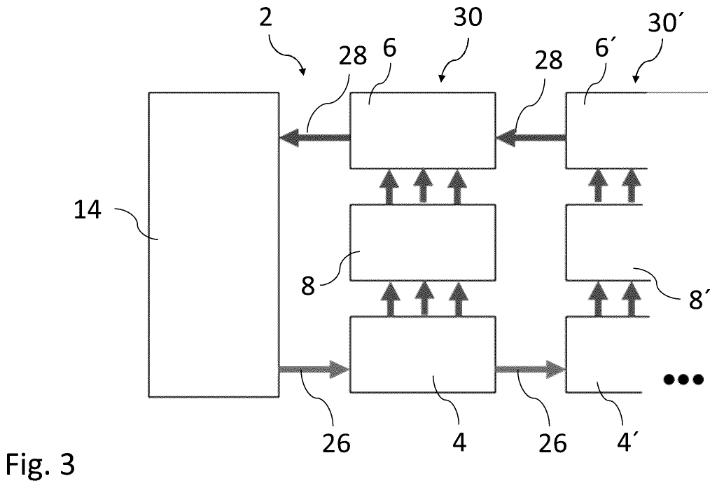

FIG. 3 is a schematic illustration of a power electronic transformer 2′ according to a second embodiment. The power electronic transformer 2′ comprises a transformer 4, for example in the form of a medium frequency transformer on ground potential, a first voltage unit 6, for example in form of or comprising a plurality of low voltage power electronics building blocks (PEBBs) and a second voltage unit 8, for example in form of or comprising a plurality of medium voltage PEBBs.

The power electronics converter 2′ further comprises a pumped two-phase cooling unit 14 comprising a two-phase cooling medium for cooling the at least one second voltage unit 8. The pumped two-phase cooling unit 14 may be a condenser.

The transformer 2′ may further comprise a two-phase-to-air heat exchanger configured to cool the two-phase cooling medium. Alternatively or additionally, the transformer 2′ may further comprises a two-phase-to-tap water heat exchanger configured to cool the two-phase cooling medium.

The two-phase cooling unit 14 further comprises at least one frequency transformer 4, particularly a medium frequency transformer. The two-phase cooling unit 14 is configured to further cool the at least one first voltage unit 6 and the at least one transformer 4.

The transformer 2′ may comprise a plurality of modular cells 30, 30′, each cell comprising or consisting of a respective transformer 4, 4′, a respective second voltage unit 8, 8′, particularly disposed above the respective transformer 4, 4′, and a respective first voltage unit 6, 6′, particularly disposed above the respective first voltage unit 8, 8′.

In this case, the two-phase cooling unit 14 advantageously comprises a tubing that runs in form of a parallel connection past the cells 30, 30′ as schematically illustrated in FIG. 3.

While the present disclosure has been described in detail in the drawings and forgoing description, such description is to be considered illustrative or exemplary and not restrictive. Variations to the disclosed embodiments can be understood and effected by those skilled in the art and practicing the claimed subject-matter, from a study of the drawings, the disclosure, and the appended claims. In the claims, the word “comprising” does not exclude other elements, and the indefinite article “a” or “an” does not exclude a plurality. The mere fact that certain elements or steps are recited in distinct claims does not indicate that a combination of these elements or steps cannot be used to advantage, specifically, in addition to the actual claim dependency, any further meaningful claim combination shall be considered disclosed.

1-15. (canceled)

16. A power electronic transformer arrangement, comprising:
at least one frequency transformer,
at least one first voltage unit for operating at a first voltage comprising first voltage power electronics building blocks,
at least one second voltage unit for operating at a second voltage comprising second voltage power electronics building blocks,
the first voltage being lower than the second voltage,
a two-phase cooling unit comprising a two-phase cooling medium for cooling the at least one second voltage unit, and
a water-cooling unit for cooling the two-phase cooling medium, wherein the water-cooling unit is further configured to cool the at least one frequency transformer.

17. The power electronic transformer arrangement of claim 16, wherein the two-phase cooling unit comprises a thermosyphon.

18. The power electronic transformer arrangement of claim 16, wherein the water-cooling unit is configured to use tap water as a coolant fluid.

19. The power electronic transformer arrangement of claim 16, wherein the water-cooling unit comprises a water-to-air heat exchanger.

20. The power electronic transformer arrangement of claim 16, wherein the water-cooling unit is configured to further cool the at least one first voltage unit.

21. The power electronic transformer arrangement of claim 16, comprising
a plurality of first voltage units comprising first voltage power electronics building blocks, and/or
a plurality of second voltage units comprising second voltage power electronics building blocks.

22. The power electronic transformer arrangement of claim 16, comprising a plurality of frequency transformers.

23. The power electronic transformer arrangement of claim 16,
wherein the at least one first voltage unit comprises at least one printed circuit board assembly comprising the first voltage power electronics building blocks, and/or
wherein the at least one second voltage unit comprises at least one printed circuit board assembly comprising the second voltage power electronics building blocks.

24. The power electronic transformer arrangement of claim 16, wherein the first voltage is equal to or less than 1500 V DC.
